(19) United States
(12) Patent Application Publication
(10) Pub. No.: US 2007/0263372 A1
(43) Pub. Date: Nov. 15, 2007

(54) CIRCUIT BOARD WITH ELECTROMAGNETIC INTERFERENCE ISOLATION AND LAYOUT METHOD THEREOF

(75) Inventor: Shu-Ming Kuo, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: MITAC INTERNATIONAL CORP., Taoyuan (TW)

(21) Appl. No.: 11/557,973

(22) Filed: Nov. 9, 2006

(30) Foreign Application Priority Data
May 9, 2006 (TW) 95116336

(51) Int. Cl. H05K 9/00

(52) U.S. Cl. 361/818

(57) ABSTRACT

A circuit board with electromagnetic interference (EMI) isolation is provided. The circuit board comprises a memory card driving circuit area for driving and accessing a memory card. In addition, there is a high-speed component area disposed in the neighborhood of the memory card riving circuit area. A moat is disposed between the memory card driving circuit area and the high-speed component area for isolating noise generated by the memory card driving circuit area.

### CROSS-REFERENCE TO RELATED APPLICATION

This application claims the priority benefit of Taiwan application serial no. 95116336, filed on May 9, 2006. All disclosure of the Taiwan application is incorporated herein by reference.

### BACKGROUND OF THE INVENTION

1. Field of the Invention

The present invention relates to a layout structure of a circuit board, and more particularly, to the layout structure of a circuit board with electromagnetic interference (EMI) isolation.

2. Description of Related Art

In a society demanding rapid flow of information, light, portable and easy-to-use storage devices having low power consumption have become increasingly important. The foremost on the list of storage devices capable of meeting the foregoing demands are memory cards or mobile discs fabricated from flash memory.

With the rapid popularization of the memory cards, the conventional storage devices such as magnetic discs and compact discs (CD) have gradually been replaced. In particular, many portable digital products such as digital camera, digital recorder, MP3 player, personal digital assistant (PDA) and mobile phone use memory cards as a storage medium. At present, memory cards already in the market include compact flash (CF) cards, smart media (SM) cards, secure digital (SD) cards, micro drive (MD) cards, memory stick (MS) cards and multimedia (MM) cards.

FIG. 1 is a diagram showing the layout of a conventional circuit board in a digital product. As shown in FIG. 1, on the circuit board 100 of a digital product that uses memory cards as a storage device, a memory card driving circuit area 102 for driving a memory card and reading data from the memory card is disposed. In addition, high-speed component devices such as universal serial bus (USB) connectors are frequently disposed in these digital products. Thus, a high-speed component area 104 is also set up on the conventional circuit board 100.

When the aforementioned digital product drives and access the data in the memory card, the memory card driving circuit area will generate noise that interferes with adjacent high-speed component area and produces noise radiation. As a result, these digital products often fail to pass standard inspection procedure.

### SUMMARY OF THE INVENTION

Accordingly, at least one objective of the present invention is to provide a layout structure of a circuit board capable of effectively isolating the noise produced in the process of driving or accessing a memory card.

To achieve these and other advantages and in accordance with the purpose of the invention, as embodied and broadly described herein, the invention provides a circuit board with electromagnetic interference (EMI) isolation. The circuit board includes a memory card driving circuit area for driving and accessing a memory card. In addition, a high-speed component area is also disposed in the neighborhood of the memory card driving circuit area. A moat is also disposed between the memory card driving circuit area and the high-speed component area for isolating noise generated by the memory card driving circuit area.

From another point of view, the present invention provides a layout method of a circuit board. The method includes disposing a memory card driving circuit area on the circuit board for driving and accessing a memory card. A high-speed component area is also disposed in the neighborhood of the memory card driving circuit area. Furthermore, a moat is cut out between the memory card driving circuit area and the high-speed component area for isolating noise generated by the memory card driving circuit area.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram showing the layout of a conventional circuit board in a digital product.

FIG. 2 is a schematic diagram showing the structural layout of a 6-layered printed circuit board.

FIG. 3 is a flow diagram showing the steps for producing a circuit board and the layout method according to one preferred embodiment of the present invention.

FIG. 4 is a schematic diagram showing the layout structure of a circuit board according to one preferred embodiment of the present invention.

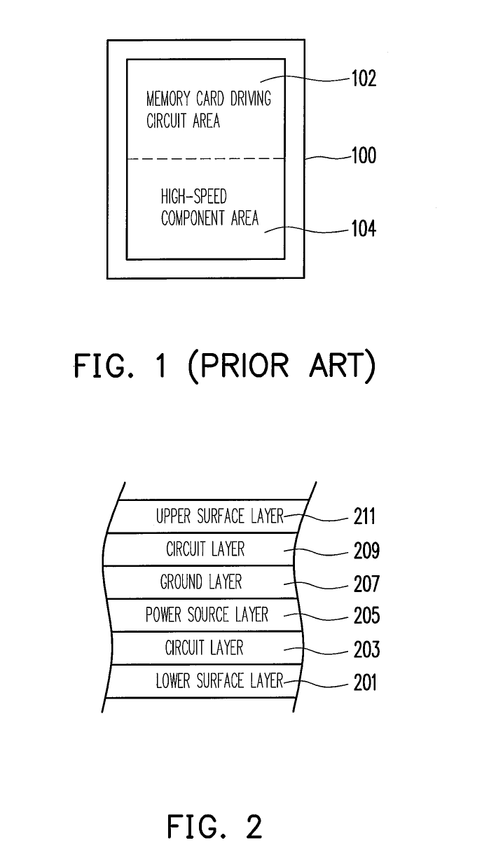

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

To provide a deeper understanding of the spirit of the present invention to people familiar with this technique, a simple explanation of the structure of the circuit board is first introduced. However, as anyone familiar with the technique may notice, the circuit board structure disclosed in the following is used an example to illustrate the spirit of the present invention only and should by no means limit the scope of the present invention. In other words, the present invention can be applied to circuit boards with other structures.

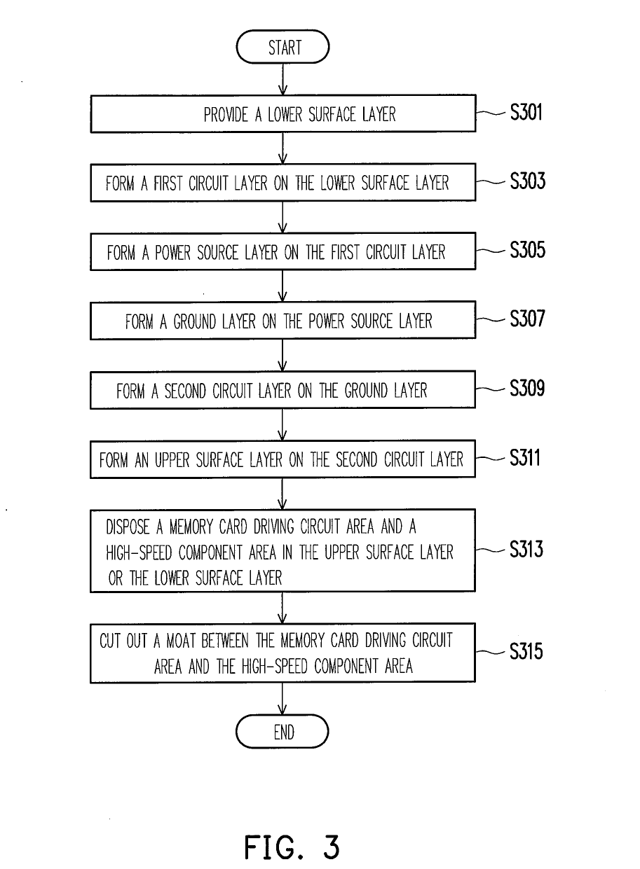

FIG. 2 is a schematic diagram showing the structural layout of a 6-layered printed circuit board. FIG. 3 is a flow diagram showing the steps for producing a circuit board and the layout method according to one preferred embodiment of the present invention. As shown in FIGS. 2 and 3, the steps from S301 to S311 in FIG. 3 are the steps for processing the circuit board and hence these steps are looked at first.

In general, a printed circuit board consists of a few resinous material layers adhered together with copper lines running inside. Therefore, when fabricating the printed circuit board shown in FIG. 2, a lower surface layer 201 is provided as mentioned in step S301. Then, as described in step S303, a circuit layer 203 is formed on the lower surface layer.

As described in step S305, a power source layer 205 is formed on the circuit layer 203. Then, as described in step S307, a ground layer 207 is formed on the power source layer 205. Comparing the power source layer 205 and the ground layer 207, the ground layer 207 has a better noise attenuation effect.

In addition, as described in step S309, another circuit layer 209 is formed on the ground layer 207, and as described in step S311, an upper surface layer 211 is formed on the circuit layer 209. In the circuit board structure shown in FIG. 2, the ground layer 207 and the power source layer 205 are disposed in the middle to facilitate correction of the signal wire. Furthermore, either the lower surface layer 201 or the upper surface layer 211 may serve as a device surface while the other one serves as a bonding surface.

Although it seems that each of the layers in the circuit board shown in FIG. 2 is packed tightly together, anyone familiar to the technology may know that resinous filler material serving as a dielectric layer may be disposed between neighboring layers. Moreover, the dielectric layer between neighboring layers can be formed using a low-k dielectric constant material.

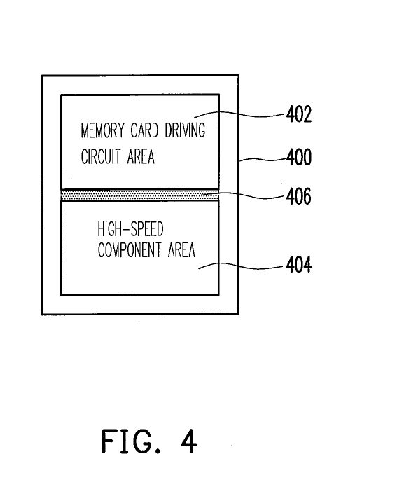

FIG. 4 is a schematic diagram showing the layout structure of a circuit board according to one preferred embodiment of the present invention. The layout of the circuit board in the present embodiment can be applied to the lower surface 201 and the upper surface 211 of the printed circuit board shown in FIG. 2 and there is no particular restriction in the present invention.

As shown in FIGS. 3 and 4, a memory card driving circuit area 402 for driving and accessing a memory card such as a CF card is disposed on the circuit board 400 as described in step S313. In one preferred embodiment, the memory card driving circuit area 402 further includes a plurality of electronic device and memory card connection ports (not shown). The memory card connection ports are used for accommodating the inserted memory card.

Furthermore, a high-speed component area 404 for accommodating, for example, global position system (GPS) connection port, audio connection port and/or universal serial bus (USB) connection port, is also disposed on the circuit board 400. Then, as described in step S315, a moat 406 is cut out between the memory card driving circuit area 402 and the high-speed component area 404. The depth of the moat 406 is identical to that of the lower surface layer 201 or the upper surface layer 211 shown in FIG. 2.

Because the moat 406 is cut out between the memory card driving circuit 402 and the high-speed component area 404 on the lower surface layer 201 or the upper surface layer 211 of the circuit board 400 in the present invention, the area between the memory card driving circuit area 402 and the high-speed component area 404 can be regarded as a high impedance region. Hence, when the radio frequency current generated by the high-speed component area 404 flows into the boundary of the moat, the current will follow a relatively lower impedance route back to the current source. Thus, the noise generated by the memory card driving circuit area 402 is prevented from affecting the high-speed component area 404, thereby reducing noise radiation produced by digital product. Consequently, the chance of digital product passing electromagnetic interference inspection is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board with electromagnetic interference (EMI) isolation, comprising:
a memory card driving circuit area for driving and accessing a memory card;
a high-speed component area adjacent to the memory card driving circuit area; and
a moat, disposed between the memory card driving circuit area and the high-speed component area.

2. The circuit board of claim 1, further comprises:
a first surface layer;
a first circuit layer formed on the first surface layer;
a power source layer formed on the first circuit layer;
a ground layer formed on the power source layer;
a second circuit layer formed on the ground layer; and
a second surface layer formed on the second circuit layer with the memory card driving circuit area, the high-speed component area and the moat.

3. The circuit board of claim 2, wherein the moat has a depth identical to that of the second surface layer.

4. The circuit board of claim 1, further comprises:
a first surface layer with the memory card driving circuit area, the high-speed component area and the moat disposed thereon;
a first circuit layer formed on the first surface layer;
a power source layer formed on the first circuit layer;
a ground layer formed on the power source layer;
a second circuit layer formed on the ground layer; and
a second surface layer formed on the second circuit layer.

5. The circuit board of claim 4, wherein the moat has a depth identical to that of the first surface layer.

6. The circuit board of claim 1, wherein the high-speed component area comprises a global position system connection port.

7. The circuit board of claim 1, wherein the high-speed component area comprises an audio connection port.

8. The circuit board of claim 1, wherein the high-speed component area comprises a universal serial bus (USB) connection port.

9. The circuit board of claim 1, wherein the memory card comprises a compact flash memory.

10. The circuit board of claim 1, wherein the memory card driving circuit area comprises:
a plurality of electronic devices; and
a memory card connection port for accommodating the memory card.

11. A layout method for a circuit board, comprising:
setting up a memory card driving circuit area for driving and accessing a memory card on the circuit board;
setting up a high-speed component area adjacent to the memory card driving circuit area on the circuit board; and
cutting out a moat between the memory card driving circuit area and the high-speed component area.

12. The layout method of claim 11, wherein the process of fabricating the circuit board comprises:
providing a first surface layer;
forming a first circuit layer on the first surface layer;
forming a power source layer on the first circuit layer;
forming a ground layer on the power source layer;
forming a second circuit layer on the ground layer; and
forming a second surface on the second circuit layer, with the memory card driving circuit area, the high-speed component area and the moat.

13. The layout method of claim 11, wherein the process of fabricating the circuit board comprises:
providing a first surface layer with the memory card driving circuit area, the high-speed component area and the moat;
forming a first circuit layer on the first surface layer;
forming a power source layer on the first circuit layer;
forming a ground layer on the power source layer;
forming a second circuit layer on the ground layer; and
forming a second surface layer on the second circuit layer.

14. The layout method of claim 11, wherein the high-speed component area comprises a global position system connection port.

15. The layout method of claim 1, wherein the high-speed component area comprises an audio connection port.

16. The layout method of claim 1, wherein the high-speed component area comprises a universal serial bus (USB) connection port.

17. The layout method of claim 11, wherein the memory card comprises a compact flash memory.
